(19) United States
(12) Patent Application Publication
(10) Pub. No.: US 2023/0163092 A1
(43) Pub. Date: May 25, 2023

(54) SEMICONDUCTOR PACKAGE

(71) Applicant: Samsung Electronics Co., Ltd., Suwon-si (KR)

(72) Inventor: Soohwan Lee, Seoul (KR)

(21) Appl. No.: 17/868,308

(22) Filed: Jul. 19, 2022

(30) Foreign Application Priority Data
Nov. 22, 2021 (KR) 10-2021-0161494

(51) Int. Cl. H01L 23/00; H01L 25/065

(52) U.S. Cl. CPC H01L 24/32; H01L 25/0657; H01L 24/16; H01L 24/73; H01L 2924/35121; H01L 2924/1431; H01L 2924/1434; H01L 2225/06513; H01L 2225/06517; H01L 2225/06524; H01L 2225/06527; H01L 2225/06541; H01L 2225/06548; H01L 24/81; H01L 2224/81203; H01L 24/96; H01L 24/97; H01L 2924/15311; H01L 2924/182; H01L 2924/186; H01L 2924/18301; H01L 2224/16148; H01L 2224/16227; H01L 2224/16238; H01L 2224/73204; H01L 2224/32145; H01L 2224/32225; H01L 2224/32059; H01L 2224/26175; H01L 2224/32054

(57) ABSTRACT

A semiconductor package includes a semiconductor chip on a package substrate, a dam structure disposed on the package substrate and surrounding the semiconductor chip, the dam structure including a first dam portion having a first length in a vertical direction, and a second dam portion connected to the first dam portion and extending from an outer side of the first dam portion, and having a second length less than the first length in the vertical direction, and an adhesive layer disposed on the package substrate, the adhesive layer including a first adhesive portion disposed between the semiconductor chip and the package substrate and overlapping the semiconductor chip in the vertical direction, and a second adhesive portion on an outer side of the semiconductor chip and including at least a part contacting a top surface of the first dam portion.

### CROSS-REFERENCE TO RELATED APPLICATION

This application is based on and claims priority under 35 U.S.C. § 119 to Korean Patent Application No. 10-2021-0161494, filed on Nov. 22, 2021, in the Korean Intellectual Property Office, the disclosure of which is incorporated by reference herein in its entirety.

### BACKGROUND

The inventive concept relates to a semiconductor package.

As a storage capacity of a semiconductor chip increases, a semiconductor package including the semiconductor chip needs to be thin and light. There is also a trend to include semiconductor chips having various functions in the semiconductor package and to conduct research for rapidly driving the semiconductor chips. In addition, studies have been actively conducted to improve the structural reliability of semiconductor packages.

### SUMMARY

The inventive concept provides a semiconductor package having improved structural reliability.

According to an aspect of the inventive concept, there is provided a semiconductor package including a package substrate, a first semiconductor chip disposed on the package substrate, a second semiconductor chip stacked on the first semiconductor chip, a dam structure disposed on the package substrate and surrounding the first semiconductor chip and the second semiconductor chip, the dam structure including a first dam portion including an inner surface having a first length in a vertical direction and facing a side surface of the first semiconductor chip, and an outer surface opposing the inner surface, and a second dam portion connected to the first dam portion and extending from the outer surface of the first dam portion and having a second length less than the first length in the vertical direction, an adhesive layer disposed on the package substrate, the adhesive layer including a first adhesive portion disposed between the first semiconductor chip and the package substrate and overlapping the first semiconductor chip in the vertical direction, a second adhesive portion disposed on an outer side of the first semiconductor chip and including at least a part contacting a top surface of the first dam portion, and a third adhesive portion being disposed between the first semiconductor chip and the second semiconductor chip and overlapping the second semiconductor chip in the vertical direction, and a molding layer disposed on the package substrate and contacting a top surface of the second dam portion.

According to another aspect of the inventive concept, there is provided a semiconductor package including a package substrate, a semiconductor chip disposed on the package substrate, a dam structure disposed on the package substrate and surrounding the semiconductor chip, the dam structure including a first dam portion having a first length in a vertical direction, and a second dam portion connected to the first dam portion and extending from an outer side of the first dam portion, and having a second length less than the first length in the vertical direction, an adhesive layer disposed on the package substrate, the adhesive layer including a first adhesive portion disposed between the semiconductor chip and the package substrate and overlapping the semiconductor chip in the vertical direction, and a second adhesive portion disposed on an outer side of the semiconductor chip and including at least a part contacting a top surface of the first dam portion, and a molding layer disposed on the package substrate.

According to another aspect of the inventive concept, there is provided a semiconductor package including a package substrate, a first semiconductor chip disposed on the package substrate, the first semiconductor chip including a first semiconductor substrate including a first active layer, a first lower chip pad disposed on a bottom surface of the first semiconductor substrate, a chip through electrode passing through at least a part of the first semiconductor substrate in a vertical direction and connected to the first active layer, a first upper chip pad disposed on a top surface of the first semiconductor substrate and connected to the chip through electrode, and a first chip connection terminal disposed between the first lower chip pad and the package substrate, a second semiconductor chip disposed on the first semiconductor chip, the second semiconductor chip including a second semiconductor substrate including a second active layer, a second lower chip pad disposed on a bottom surface of the second semiconductor substrate, and a second chip connection terminal disposed between the second lower chip pad and the first upper chip pad, a dam structure disposed on the package substrate and surrounding the first semiconductor chip and the second semiconductor chip, the dam structure including a first dam portion including an inner surface having a first length in a vertical direction and facing a side surface of the first semiconductor chip and an outer surface opposing the inner surface, and a second dam portion connected to the first dam portion extending from the outer surface of the first dam portion and having a second length less than the first length in the vertical direction, an adhesive layer disposed on the package substrate, the adhesive layer including a first adhesive portion overlapping the first semiconductor chip in the vertical direction and disposed between the first semiconductor chip and the package substrate to surround the first chip connection terminal, a second adhesive portion disposed on an outer side of the first semiconductor chip and including at least a part contacting a top surface of the first dam portion, and a third adhesive portion overlapping the second semiconductor chip in the vertical direction and disposed between the first semiconductor chip and the second semiconductor chip to surround the second chip connection terminal, and a molding layer disposed on the package and contacting a top surface of the second dam portion.

A semiconductor package according to an example embodiment of the inventive concept may include a dam structure disposed on a package substrate and surrounding a semiconductor chip, and an adhesive layer disposed on an inner side from a side surface of the semiconductor package such that at least a part of the adhesive layer is supported by the dam structure and fixing the semiconductor chip to the package substrate. Thus, the adhesive layer of the semiconductor package may not be observed from a side surface of the semiconductor package, thereby reducing delamination between the adhesive layer and the molding layer and improving the structural reliability of the semiconductor package.

Moreover, a method of manufacturing a semiconductor package according to an example embodiment of the inventive concept may include forming an adhesive layer on a package substrate after forming a dam structure on the package substrate, and removing at least a part of the adhesive layer and at least a part of the dam structure through a dicing blade. As the dam structure may be disposed on the package substrate, physical damage to the package substrate may be prevented from occurring due to the dicing blade.

### BRIEF DESCRIPTION OF THE DRAWINGS

Embodiments of the inventive concept will be more clearly understood from the following detailed description taken in conjunction with the accompanying drawings in which:

FIG. 1 is a cross-sectional view of a semiconductor package according to an example embodiment of the inventive concept;

FIG. 2 is a plan view taken along II-IF cross-sectional line;

FIG. 3 is an enlarged view of a region A of FIG. 1;

FIGS. 4A to 4C are views of first to third dam structures according to an example embodiment of the inventive concept;

FIG. 5 is a cross-sectional view of a semiconductor package according to an example embodiment of the inventive concept;

FIG. 6 is a flowchart of a method of manufacturing a semiconductor package, according to an example embodiment of the inventive concept; and

FIGS. 7 to 14 are views showing operations of a method of manufacturing a semiconductor package, according to an example embodiment of the inventive concept.

### DETAILED DESCRIPTION OF THE EMBODIMENTS

Hereinafter, embodiments of the inventive concept will be described in detail with reference to the accompanying drawings.

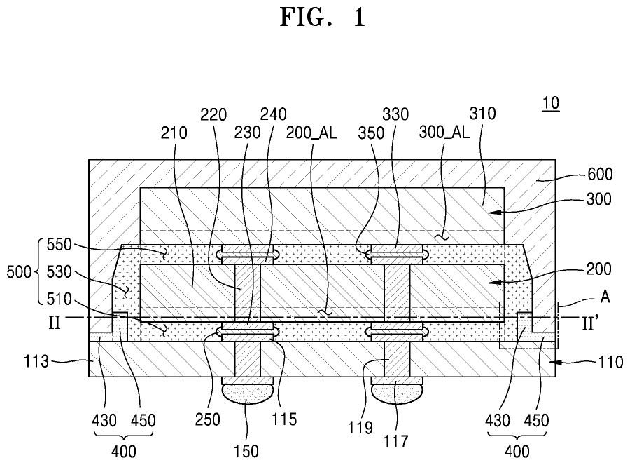

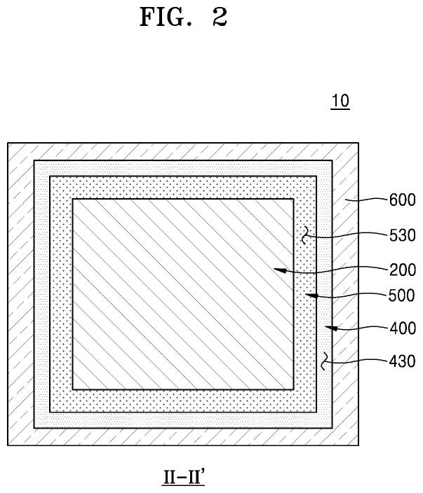

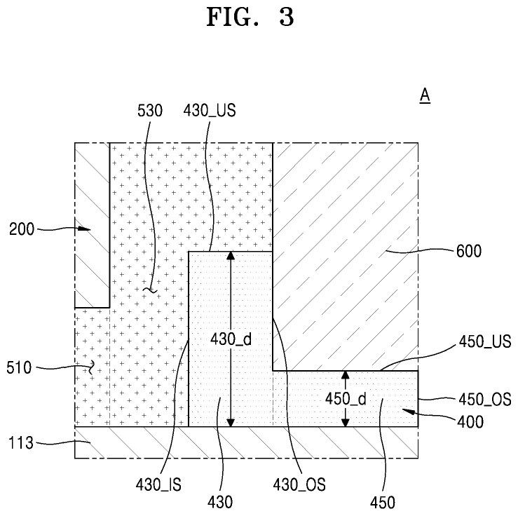

FIG. 1 is a cross-sectional view of a semiconductor package 10 according to an example embodiment of the inventive concept. FIG. 2 is a plan view taken along II-IF cross-sectional line. FIG. 3 is an enlarged view of a region A of FIG. 1.

Referring to FIGS. 1 to 3 together, the semiconductor package 10 according to an example embodiment of the inventive concept may include a package substrate 110, a package connection terminal 150, a first semiconductor chip 200, a second semiconductor chip 300, a dam structure 400, an adhesive layer 500, and a molding layer 600.

The package substrate 110 may be configured to support the first semiconductor chip 200 and the second semiconductor chip 300 and to electrically connect the first semiconductor chip 200 and the second semiconductor chip 300 to an external device.

In an example embodiment, the package substrate 110 may be a printed circuit board (PCB). However, the package substrate 110 may include various types of substrates such as a ceramic substrate, a wafer substrate, etc., without being limited to a structure and a material of the PCB.

In an example embodiment, the package substrate 110 may include a substrate insulating layer 113, an upper substrate pad 115, a lower substrate pad 117, and a substrate through electrode 119.

In an example embodiment, a material of the substrate insulating layer 113 may include an oxide or a nitride. For example, the material of the substrate insulating layer 113 may include a silicon oxide or a silicon nitride. However, without being limited thereto, the material of the substrate insulating layer 113 may include at least any one of phenol resin, epoxy resin, and polyimide.

In an example embodiment, the upper substrate pad 115 may be a pad disposed on a top surface of the substrate insulating layer 113 and configured to electrically connect the first semiconductor chip 200 to the package substrate 110. More specifically, the upper substrate pad 115 may be a pad on which a first chip connection terminal 250 of the first semiconductor chip 200 is mounted.

In an example embodiment, the lower substrate pad 117 may be a pad disposed on a bottom surface of the substrate insulating layer 113 and configured to electrically connect the package substrate 110 having mounted thereon the first semiconductor chip 200 and the second semiconductor chip 300 to the external device. Specifically, the lower substrate pad 117 may be a pad on which the package connection terminal 150 is mounted.

In an example embodiment, the substrate through electrode 119 may be an electrode of a conductive material passing through at least a part of the substrate insulating layer 113 in the vertical direction. Hereinbelow, the horizontal direction may be defined as a direction parallel to a direction in which the top surface of the substrate insulating layer 113 extends (that is, a width direction of the substrate insulating layer 113), and the vertical direction may be defined as a direction perpendicular to the direction in which the top surface of the substrate insulating layer 113 extends (that is, a thickness direction of the substrate insulating layer 113).

In an example embodiment, the substrate through electrode 119 may pass through the substrate insulating layer 113 in the vertical direction to electrically connect the upper substrate pad 115 to the lower substrate pad 117.

The package substrate 110 may further include a substrate line pattern (not shown) of a conductive material, which extends in the horizontal direction in the substrate insulating layer 113. Moreover, the substrate line pattern may form a plurality of layers inside the substrate insulating layer 113. A plurality of substrate line patterns may be electrically connected by the substrate through electrode 119.

In an example embodiment, a part of the substrate line pattern may be connected to the upper substrate pad 115 via the substrate through electrode 119, and another part of the substrate line pattern may be connected to the lower substrate pad 117 via the substrate through electrode 119.

The package connection terminal 150 may be a connection terminal that is attached to the lower substrate pad 117 and electrically connects the first semiconductor chip 200 and the second semiconductor chip 300 mounted on the package substrate 110 to an external device.

In an example embodiment, the package connection terminal 150 may be a solder ball of a metal material including or formed of at least any one of tin or stannum (Sn), silver or argentum (Ag), copper or cuprum (Cu), and aluminum (Al).

The first semiconductor chip 200 may be a semiconductor chip mounted on the package substrate 110. The first semiconductor chip 200 may include a first semiconductor substrate 210 including a first active layer 200_AL, a chip through electrode 220, a first lower chip pad 230, a first upper chip pad 240, and the first chip connection terminal 250.

In an example embodiment, the first semiconductor chip 200 may include a memory semiconductor chip. For example, the memory semiconductor chip may include a volatile memory semiconductor chip such as dynamic random-access memory (DRAM) or static random-access memory (SRAM), and a non-volatile memory semiconductor chip such as phase-change random access memory (PRAM), magneto-resistive random-access memory (MRAM), ferroelectric random-access memory (FeRAM), or resistive random-access memory (RRAM).

However, without being limited thereto, the first semiconductor chip 200 may include a logic semiconductor chip. For example, the logic semiconductor chip may include a logic semiconductor chip such as a central processor unit (CPU), a microprocessor unit (MPU), a graphics processor unit (GPU), or an application processor (AP).

A material of the first semiconductor substrate 210 of the first semiconductor chip 200 may include silicon (Si). The material of the first semiconductor substrate 210 may include a semiconductor element such as germanium (Ge), or a compound semiconductor such as silicon carbide (SiC), gallium arsenide (GaAs), indium arsenide (InAs), and indium phosphide (InP). However, the material of the first semiconductor substrate 210 is not limited to the foregoing description.

In an example embodiment, a lower portion of the first semiconductor substrate 210 may include the first active layer 200_AL. The first active layer 200_AL may include a plurality of individual devices of various types. For example, the plurality of individual devices may include various microelectronic devices, for example, an image sensor such as a complementary metal-oxide semiconductor (CMOS) transistor, a metal-oxide-semiconductor field effect transistor (MOSFET), a system large scale integration (LSI), a CMOS imaging sensor (CIS), etc., a micro-electro-mechanical system (MEMS), an active device, a passive device, and the like.

The chip through electrode 220 of the first semiconductor chip 200 may pass through at least a part of the first semiconductor substrate 210 in the vertical direction, and may be electrically connected to the plurality of individual devices in the first active layer 200_AL.

For example, the chip through electrode 220 may pass through the first semiconductor substrate 210 in the vertical direction to connect the first upper chip pad 240 to the first lower chip pad 230. However, without being limited to the foregoing description, the chip through electrode 220 may pass through at least a part of the first semiconductor substrate 210 in the vertical direction to connect the first upper chip pad 240 to the plurality of individual devices in the first active layer 200_AL.

In an example embodiment, the chip through electrode 220 may include a conductive plug (not shown) and a conductive barrier film (not shown). The conductive plug may penetrate at least a part of the first semiconductor substrate 210, and the conductive barrier film may enclose a sidewall of the conductive plug. For example, the conductive plug may have a cylindrical shape, and the conductive barrier film may have a cylindrical shape surrounding the sidewall of the conductive plug.

The first lower chip pad 230 of the first semiconductor chip 200 may be disposed on a bottom surface of the first semiconductor substrate 210 and may be electrically connected to the plurality of individual devices in the first active layer 200_AL. The first lower chip pad 230 may be electrically connected to the chip through electrode 220.

In an example embodiment, the first semiconductor chip 200 may further include a passivation layer (not shown) of an insulating material, which is disposed on the bottom surface of the first semiconductor substrate 210 to surround a side portion of the first lower chip pad 230. The passivation layer may expose a bottom surface of the first lower chip pad 230.

The first upper chip pad 240 of the first semiconductor chip 200 may be disposed on a top surface of the first semiconductor substrate 210 to contact the chip through electrode 220. The first upper chip pad 240 may be a pad of a conductive material on which a second chip connection terminal 350 to be described later is mounted.

In an example embodiment, materials of the first lower chip pad 230 and the first upper chip pad 240 may include Cu. However, without being limited thereto, the materials of the first lower chip pad 230 and the first upper chip pad 240 may include metals such as nickel (Ni), gold or aurum (Au), Al, tungsten (W), titanium (Ti), tantalum (Ta), indium (In), molybdenum (Mo), manganese (Mn), cobalt (Co), Sn, magnesium (Mg), rhenium (Re), beryllium (Be), gallium (Ga), ruthenium (Ru), etc., or an alloy thereof.

The first chip connection terminal 250 of the first semiconductor chip 200 may be attached to the first lower chip pad 230 to electrically connect the first semiconductor chip 200 to the package substrate 110. More specifically, the first chip connection terminal 250 may be disposed between the first lower chip pad 230 of the first semiconductor chip 200 and the upper substrate pad 115 of the package substrate 110.

In an example embodiment, the first chip connection terminal 250 may be a solder ball of a metal material including at least any one of Sn, Ag, Cu, and Al.

The second semiconductor chip 300 may be a semiconductor chip mounted on the first semiconductor chip 200. In an example embodiment, the second semiconductor chip 300 may include a second semiconductor substrate 310 including a second active layer 300_AL, a second lower chip pad 330, and a second chip connection terminal 350. Hereinbelow, redundant descriptions of the first semiconductor chip 200 and the second semiconductor chip 300 are omitted and differences therebetween are mainly described.

In an example embodiment, the first semiconductor chip 200 and the second semiconductor chip 300 may be semiconductor chips of different types. Thus, the semiconductor package 10 may be a system-in-package (SIP) where a plurality of semiconductor chips 200 and 300 of different types are electrically interconnected to operate as one system. However, without being limited thereto, the first semiconductor chip 200 and the second semiconductor chip 300 may be semiconductor chips of the same type.

In an example embodiment, the second semiconductor chip 300 may include a memory semiconductor chip. However, without being limited thereto, the second semiconductor chip 300 may include a logic semiconductor chip.

In an example embodiment, a lower portion of the second semiconductor substrate 310 may include the second active layer 300_AL. The second active layer 300_AL may include a plurality of individual devices of different types.

The second lower chip pad 330 of the second semiconductor chip 300 may be disposed on a bottom surface of the second semiconductor substrate 310 and may be electrically connected to the plurality of individual devices in the second active layer 300_AL.

In an example embodiment, the second semiconductor chip 300 may further include a second passivation layer (not shown) of an insulating material, which is disposed on the bottom surface of the second semiconductor substrate 310 to surround a side portion of the second lower chip pad 330. The second passivation layer may expose a bottom surface of the second lower chip pad 330.

The second chip connection terminal 350 of the second semiconductor chip 300 may be attached to the second lower chip pad 330 to electrically connect the first semiconductor chip 200 to the second semiconductor chip 300. More specifically, the second chip connection terminal 350 may be disposed between the first upper chip pad 240 of the first semiconductor chip 200 and the second lower chip pad 330 of the second semiconductor chip 200.

In an example embodiment, the second chip connection terminal 350 may be a solder ball of a metal material including at least any one of Sn, Ag, Cu, and Al.

The dam structure 400 may be a structure that is mounted on the package substrate 110 and surrounds the first semiconductor chip 200 and the second semiconductor chip 300. This is evidenced from a plan view taken along II-IF cross-sectional line. In an example embodiment, the dam structure 400 may include a first dam portion 430 and a second dam portion 450.

The first dam portion 430 may be a part of the dam structure 400. The first dam portion 430 has a first length 430_d in the vertical direction and overlaps an adhesive layer 500 to be described later in the vertical direction. In an example embodiment, the first dam portion 430 may include an inner surface 430_IS facing a side surface of the first semiconductor chip 200, an outer surface 430_OS opposing the inner surface 430_IS, and a top surface 430_US connecting the inner surface 430_IS to the outer surface 430_OS and facing a top surface of the semiconductor package 10.

In an example embodiment, the inner surface 430_IS and the top surface 430_US of the first dam portion 430 may contact a part of the adhesive layer 500, and the outer surface 430_OS of the first dam portion 430 may contact a part of the molding layer 600.

In an example embodiment, the first length 430_d of the first dam portion 430 in the vertical direction may be about 8 micrometers to about 100 micrometers. However, the first length 430_d of the first dam portion 430 in the vertical direction is not limited to the values described above.

In an example embodiment, a level of the top surface 430_US of the first dam portion 430 may be lower than a level of the top surface of the first semiconductor chip 200. The level thereof may be defined as a height formed by a surface of a component of the semiconductor package 10 in the vertical direction from the top surface of the package substrate 110.

For example, the level of the top surface 430_US of the first dam portion 430 may be higher than a level of a bottom surface of the first semiconductor chip 200 and may be lower than the level of the top surface of the first semiconductor chip 200. However, without being limited thereto, the level of the top surface 430_US of the first dam portion 430 may be lower than the level of the bottom surface of the first semiconductor chip 200.

The second dam portion 450 may be a part of the dam structure 400. The second dam portion 450 is connected to the first dam portion 430 and extends from the outer surface 430_OS of the first dam portion 430. The second dam portion 450 has a second length 450_d that is less than the first length 430_d in the vertical direction. The second dam portion 450 may also overlap the molding layer 600 to be described later in the vertical direction.

In an example embodiment, the second dam portion 450 may include an outer surface 450_OS forming an outermost side of the dam structure 400 and a top surface 450 US facing the top surface of the semiconductor package 10.

In an example embodiment, the top surface 450 US of the second dam portion 450 may contact the molding layer 600. The top surface 450 US of the second dam portion 450 may have a planar shape that extends in a direction parallel to a direction in which the top surface of the package substrate 110 extends. It will be appreciated that “planar,” “co-planar,” “planarization,” etc., as used herein refer to structures (e.g., surfaces) that need not be perfectly geometrically planar, but may include acceptable variances that may result from standard manufacturing processes.

In an example embodiment, the outer surface 450_OS of the second dam portion 450 may be on the same plane (i.e., coplanar) as a side surface (outer surface) of the molding layer 600. That is, the outer surface 450_OS of the second dam portion 450 may be on the same plane as the side surface of the semiconductor package 10, and when the exterior of the semiconductor package 10 is observed, the outer surface 450_OS of the second dam portion 450 may be observed.

In an example embodiment, the second length 450_d of the second dam portion 450 in the vertical direction may be less than or equal to a half of the first length 430_d of the first dam portion 430 in the vertical direction. For example, the second length 450_d of the second dam portion 450 in the vertical direction may be about 5% to about 45% of the first length 430_d of the first dam portion 430 in the vertical direction. However, the second length 450_d of the second dam portion 450 in the vertical direction is not limited to the values described above.

In an example embodiment, the outer surface 430_OS of the first dam portion 430 may be on the same plane as a side surface of the adhesive layer 500. More specifically, the outer surface 430_OS of the first dam portion 430, a part of the side surface of the adhesive layer 500, and an inner surface of the molding layer 600 may be on the same plane.

As described below, at least a part of the dam structure 400 and at least a part of the adhesive layer 500 may be removed by a dicing blade 1100 of FIG. 11, such that the outer surface 430_OS of the first dam portion 430 and a side surface of the adhesive layer 500 may be arranged on the same plane.

In an example embodiment, when a cross-section of the dam structure 400 is viewed, the cross-section of the dam structure 400 may have a shape of the alphabetical letter L or a left and right reversed shape of the alphabetical letter L.

In an example embodiment, a material of the dam structure 400 may include at least any one of a photo imageable dielectric (PID) material and a photosensitive polyimide (PSPI), which are capable of being subject to a photolithography process.

However, without being limited thereto, the material of the dam structure 400 may include at least any one of silicon oxide (SiO₂) and an epoxy molding compound (EMC).

In an example embodiment, the material of the dam structure 400 may be substantially the same as the material of the molding layer 600 to be described later. For example, the material of the dam structure 400 and the material of the molding layer 600 may include an EMC. When the material of the dam structure 400 and the material of the molding layer 600 are the same as each other, the dam structure 400 and the molding layer 600 may be integrated with each other. When the dam structure 400 and the molding layer 600 are integrated, delamination between the dam structure 400 and the molding layer 600 may be reduced, thereby improving the structural reliability of the semiconductor package 10.

The adhesive layer 500 may be a layer mounted on the package substrate 110 to fix the first semiconductor chip 200 to the package substrate 110 and to fix the second semiconductor chip 300 to the first semiconductor chip 200.

In an example embodiment, the adhesive layer 500 may include a first adhesive portion 510 disposed between the first semiconductor chip 200 and the package substrate 110 and overlaps the first semiconductor chip 200 in the vertical direction, a second adhesive portion 530 disposed on an outer side of the first semiconductor chip 200 and has at least a part contacting the top surface 430_US of the first dam portion 430, and a third adhesive portion 550 disposed between the first semiconductor chip 200 and the second semiconductor chip 300 and overlaps the second semiconductor chip 300 in the vertical direction.

The adhesive layer 500 may overlap the first dam portion 430 of the dam structure 400 in the vertical direction, but may not overlap the second dam portion 450 in the vertical direction. That is, the adhesive layer 500 may be provided on an inner side of the second dam portion 450.

When the exterior of the semiconductor package 10 is observed, the adhesive layer 500 may not be observed. Therefore, delamination between the adhesive layer 500 and the molding layer 600 may be reduced, and the structural reliability of the semiconductor package 10 may be improved.

In an example embodiment, a part of the second adhesive portion 530 of the adhesive layer 500 may overlap the first dam portion 430 in the vertical direction. A part of a side surface of the second adhesive portion 530 may be arranged on the same plane as the outer surface 430_OS of the first dam portion 430.

In an example embodiment, the material of the adhesive layer 500 may include a non-conductive film (NCF). However, without being limited thereto, the material of the adhesive layer 500 may include at least any one of non-conductive paste (NCP), insulating polymer, and epoxy resin.

In an example embodiment, the adhesive layer 500 may enclose the first semiconductor chip 200. More specifically, the adhesive layer 500 may surround the top surface, the bottom surface, and the side surfaces of the first semiconductor chip 200.

The molding layer 600 may be mounted on the package substrate 110 to surround the dam structure 400, the adhesive layer 500, and the second semiconductor chip 300. In an example embodiment, at least a part of the molding layer 600 may contact the second dam portion 450 of the dam structure 400.

In an example embodiment, the molding layer 600 may cover the top surface of the second semiconductor chip 300. However, the top surface of the molding layer 600 may be on the same plane as the top surface of the second semiconductor chip 300. That is, the top surface of the second semiconductor chip 300 may be exposed (i.e., not covered) by the molding layer 600.

In an example embodiment, the molding layer 600 may contact the second dam portion 450 of the dam structure 400 and the second adhesive portion 530 of the adhesive layer 500.

In an example embodiment, the material of the insulating layer 600 may include at least any one of insulating polymer and epoxy resin. For example, the molding layer 600 may include an EMC.

The semiconductor package 10 according to an example embodiment of the inventive concept may include the dam structure 400 mounted on the package substrate 110 to support at least a part of the adhesive layer 500 which is provided on an inner side of the semiconductor package 10 from the side surface of the semiconductor package 10. Thus, the adhesive layer 500 of the semiconductor package 10 may not be observed from the side surface of the semiconductor package 10, such that delamination between the adhesive layer 500 and the molding layer 600 may be reduced, thereby improving the structural reliability of the semiconductor package 10.

Moreover, after an operation of forming the dam structure 400 on the package substrate 110, an operation of forming the adhesive layer 500 on the package substrate 110 and an operation of removing at least a part of the adhesive layer 500 and at least a part of the dam structure 400 through the dicing blade 1100 of FIG. 11 may be performed, thereby preventing physical damage to the package substrate 110 from occurring due to the dicing blade 1100.

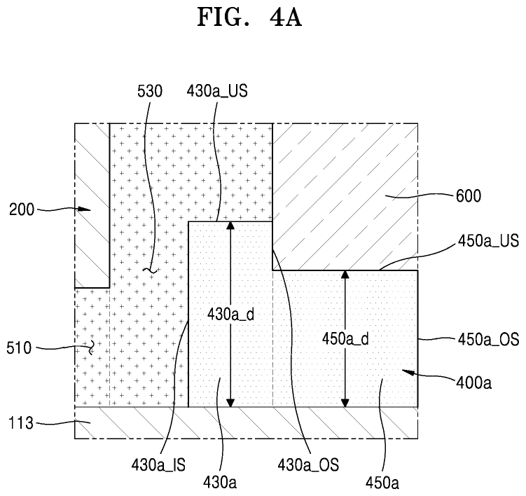

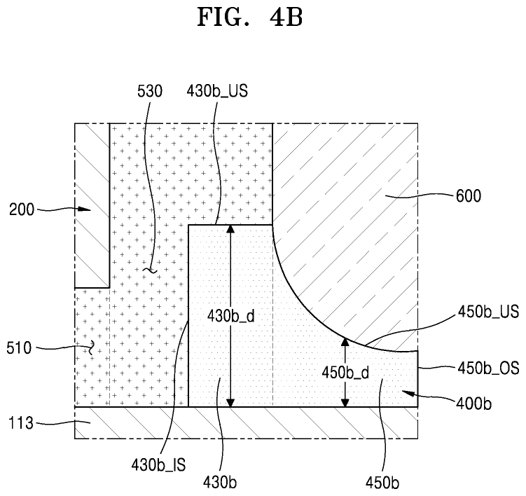

FIGS. 4A to 4C are views of first to third dam structures 400a, 400b, and 400c, according to an example embodiment of the inventive concept. Hereinbelow, redundant descriptions of the dam structure 400 described with reference to FIGS. 1 to 3 and the first to third dam structures 400a, 400b, and 400c of FIGS. 4A to 4C are omitted and differences therebetween are mainly described.

Referring to FIG. 4A, the first dam structure 400a according to an example embodiment of the inventive concept may include a first dam portion 430a and a second dam portion 450a.

In an example embodiment, the first dam portion 430a may be a part of the dam structure 400a. The first dam portion 430a has a first length 430a_d in the vertical direction and overlaps the second adhesive portion 530 of the adhesive layer 500 in the vertical direction. The first dam portion 430a may include an inner surface 430a IS facing a side surface of the first semiconductor chip 200 and contacting the second adhesive portion 530, an outer surface 430a OS opposing the inner surface 430a IS and contacting the molding layer 600, and a top surface 430a US facing the top surface of the semiconductor package 10 and contacting the second adhesive portion 530.

The second dam portion 450a may be a part of the dam structure 400a. The second dam portion 450a is connected to the first dam portion 430a and extends from the outer surface 430a OS of the first dam portion 430a. The second dam portion 450a has a second length 450a_d that is less than the first length 430a_d in the vertical direction. The second dam portion 450a may also overlap the molding layer 600 in the vertical direction. In an example embodiment, the second dam portion 450a may include an outer surface 450a OS that forms an outermost side of the dam structure 400a and is arranged on the same plane as the side surface of the semiconductor package 10, and a top surface 450a US that faces the top surface of the semiconductor package 10 and contacts the molding layer 600.

In an example embodiment, the second length 450a_d of the second dam portion 450a in the vertical direction may be greater than or equal to a half of the first length 430a_d of the first dam portion 430a in the vertical direction. For example, the second length 450a_d of the second dam portion 450a in the vertical direction may be about 55% to about 95% of the first length 430a_d of the first dam portion 430a in the vertical direction. However, the second length 450a_d of the second dam portion 450a in the vertical direction is not limited to the values described above.

Referring to FIG. 4B, the second dam structure 400b according to an example embodiment of the inventive concept may include a first dam portion 430b and a second dam portion 450b.

In an example embodiment, the first dam portion 430b may be a part of the dam structure 400b. The first dam portion 430b has a first length 430b_d in the vertical direction and overlaps the second adhesive portion 530 of the adhesive layer 500 in the vertical direction. The first dam portion 430b may include an inner surface 430bIS facing the side surface of the first semiconductor chip 200 and contacting the second adhesive portion 530, and a top surface 430b_US facing the top surface of the semiconductor package 10 and contacting the second adhesive portion 530.

The second dam portion 450b may be a part of the dam structure 400b. The second dam portion 450b is connected to the first dam portion 430b and extends from an outer side, opposite to the inner surface 430b IS, of the first dam portion 430b. The second dam portion 450b has a second length 450b_d that is less than the first length 430b_d in the vertical direction. The second dam portion 450b may also overlap the molding layer 600 in the vertical direction.

In an example embodiment, the second dam portion 450b may include an outer surface 450b_OS that forms an outermost side of the dam structure 400b and is arranged on the same plane as the side surface of the semiconductor package 10, and a top surface 450b_US that connects the top surface of the first dam portion 430b to the outer surface 450b_OS of the second dam portion 450b.

In an example embodiment, the top surface 450b_US of the second dam portion 450b may have a curved surface shape. More specifically, the top surface 450b_US of the second dam portion 450b may be provided in a curved surface shape such that the second length 450b_d of the second dam portion 450b gradually decreases in a direction away from the side surface of the first semiconductor chip 200. For example, the top surface 450b_US of the second dam portion 450b may have a concave up shape.

Referring to FIG. 4C, the third dam structure 400c according to an example embodiment of the inventive concept may include a first dam portion 430c, a second dam portion 450c, and a third dam portion 470c.

In an example embodiment, the first dam portion 430c may be a part of the dam structure 400c. The first dam portion 430c has a first length 430c_d in the vertical direction and overlaps the second adhesive portion 530 of the adhesive layer 500 in the vertical direction. The first dam portion 430c may include an inner surface 430c_IS facing a side surface of the first semiconductor chip 200 and contacting the second adhesive portion 530, an outer surface 430c_OS opposing the inner surface 430c_IS and contacting the molding layer 600, and a top surface 430c_US facing the top surface of the semiconductor package 10 and contacting the second adhesive portion 530.

The second dam portion 450c may be a part of the dam structure 400c. The second dam portion 450c is connected to the first dam portion 430c and extends from the outer surface 430c_OS of the first dam portion 430c. The second dam portion 450c has a second length 450c_d that is less than the first length 430c_d in the vertical direction. The second dam portion 450c may overlap the molding layer 600 in the vertical direction. The second dam portion 450c may include an outer surface 450c_OS facing the side surface of the semiconductor package 10 and contacting the molding layer 600, and a top surface 450c_US facing the top surface of the semiconductor package 10 and contacting the molding layer 600.

The third dam portion 470c may be a part of the dam structure 400c. The third dam portion 470c is connected to the second dam portion 450c and extends from the outer surface 450c_OS of the second dam portion 450c. The third dam portion 470c has a third length 470c_d that is less than the second length 450c_d in the vertical direction. The third dam portion 470c may include an outer surface 470c_OS that forms an outermost side of the dam structure 400c and is arranged on the same plane as the side surface of the semiconductor package 10, and a top surface 470c_US that faces the top surface of the semiconductor package 10 and contacts the molding layer 600.

That is, a cross-section of the dam structure 400c may be provided in a stepped shape. In an example embodiment, in an operation of removing a part of the dam structure 400c and a part of the adhesive layer 500 through a dicing blade, when the dicing blade removes the dam structure 400c and the adhesive layer 500 a plurality of times, the cross-section of the dam structure 400c may be provided in a stepped shape.

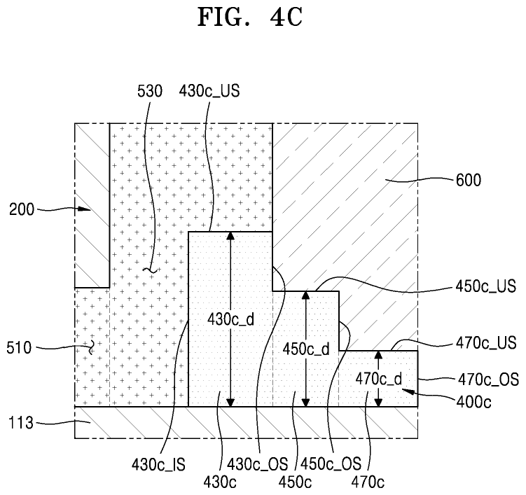

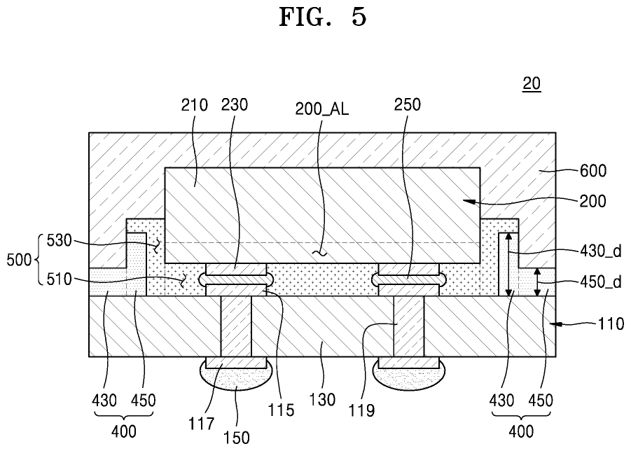

FIG. 5 is a cross-sectional view of a semiconductor package 20 according to an example embodiment of the inventive concept.

Hereinbelow, redundant descriptions of the semiconductor package 10 of FIGS. 1 to 3 and the semiconductor package 20 of FIG. 5 are omitted, and differences therebetween are mainly described.

The semiconductor package 20 according to an example embodiment of the inventive concept may include the package substrate 110, the package connection terminal 150, the first semiconductor chip 200, the dam structure 400, the adhesive layer 500, and the molding layer 600. That is, the semiconductor package 20 according to the inventive concept may include one semiconductor chip 200.

In an example embodiment, the dam structure 400 may be a structure that is disposed on the package substrate 110 and surrounds the first semiconductor chip 200. This evidenced from the plan view taken along II-IF cross-sectional line. In an example embodiment, the dam structure 400 may include the first dam portion 430 and the second dam portion 450.

The first dam portion 430 may be a portion of the dam structure 400, which has the first length 430_d in the vertical direction and overlaps the adhesive layer 500 to be described later in the vertical direction.

In an example embodiment, a level of the top surface of the first dam portion 430 may be lower than a level of the top surface of the first semiconductor chip 200. For example, the level of the top surface of the first dam portion 430 may be higher than the level of the bottom surface of the first semiconductor chip 200 and lower than the level of the top surface of the first semiconductor chip 200. However, without being limited thereto, the level of the top surface of the first dam portion 430 may be lower than that of the bottom surface of the first semiconductor chip 200

The second dam portion 450 may be a part of the dam structure 400. The second dam portion 450 is connected to the first dam portion 430 and extends from an outer side of the first dam portion 430. The second dam portion 450 has a second length 450_d that is less than the first length 430_d in the vertical direction. The second dam portion 450 may also contact the molding layer 600.

In an example embodiment, the outer surface of the second dam portion 450 may be on the same plane as the side surface of the molding layer 600. That is, the outer surface of the second dam portion 450 may be on the same plane as the side surface of the semiconductor package 20, and when the exterior of the semiconductor package 20 is observed, a part of the second dam portion 450 may be observed.

In an example embodiment, the outer surface of the first dam portion 430 may be on the same plane as a side surface of the adhesive layer 500. At least a part of the dam structure 400 and at least a part of the adhesive layer 500 may be removed by a dicing blade, such that the outer surface of the first dam portion 430 and the side surface of the adhesive layer 500 may be arranged on the same plane.

In an example embodiment, when the cross-section of the dam structure 400 is viewed, the cross-section of the dam structure 400 may have a shape of the alphabetical letter L or a left and right reversed shape of the alphabetical letter L.

In an example embodiment, the material of the dam structure 400 may include at least any one of a PID material and PSPI, which are capable of being subject to the photolithography process. However, without being limited thereto, the material of the dam structure 400 may include at least any one of Sift and an EMC.

In an example embodiment, the material of the dam structure 400 may be substantially the same as the material of the molding layer 600. For example, the material of the dam structure 400 and the material of the molding layer 600 may include an EMC. When the material of the dam structure 400 and the material of the molding layer 600 are the same as each other, the dam structure 400 and the molding layer 600 may be integrated. When the dam structure 400 and the molding layer 600 are integrated, delamination between the dam structure 400 and the molding layer 600 may be reduced, thereby improving the structural reliability of the semiconductor package 10.

The adhesive layer 500 may be a layer mounted on the package substrate 110 to fix the first semiconductor chip 200 to the package substrate 110.

In an example embodiment, the adhesive layer 500 may include a first adhesive portion 510 disposed between the first semiconductor chip 200 and the package substrate 110 and overlapping the first semiconductor chip 200 in the vertical direction, and a second adhesive portion 530 disposed on an outer side of the first semiconductor chip 200 and has at least a part contacting the top surface of the first dam portion 430.

The adhesive layer 500 may overlap the first dam portion 430 of the dam structure 400 in the vertical direction, but may not overlap the second dam portion 450 in the vertical direction. For example, the adhesive layer 500 may be provided on the inner side of the second dam portion 450.

When the exterior of the semiconductor package 20 is observed, the adhesive layer 500 may not be observed. Therefore, delamination between the adhesive layer 500 and the molding layer 600 may be reduced, and the structural reliability of the semiconductor package 20 may be improved.

In an example embodiment, a part of the second adhesive portion 530 of the adhesive layer 500 may overlap the first dam portion 430 in the vertical direction. A part of the side surface of the second adhesive portion 530 may be arranged on the same plane as the outer surface of the first dam portion 430.

In an example embodiment, the material of the adhesive layer 500 may include an NCF. However, without being limited to the foregoing description, the material of the adhesive layer 500 may include at least any one of an NCP, insulating polymer, and epoxy resin.

The semiconductor package 20 according to an example embodiment of the inventive concept may include the dam structure 400 mounted on the package substrate 110 to support at least a part of the adhesive layer 500 which is provided on an inner side of the semiconductor package 20 from the side surface of the semiconductor package 20. Thus, the adhesive layer 500 of the semiconductor package 20 may not be observed from the side surface of the semiconductor package 20, such that delamination between the adhesive layer 500 and the molding layer 600 may be reduced, thereby improving the structural reliability of the semiconductor package 20.

Moreover, after an operation of forming the dam structure 400 on the package substrate 110, an operation of forming the adhesive layer 500 on the package substrate 110 and an operation of removing at least a part of the adhesive layer 500 and at least a part of the dam structure 400 through a dicing blade may be performed, thereby preventing physical damage to the package substrate 110 from occurring due to the dicing blade.

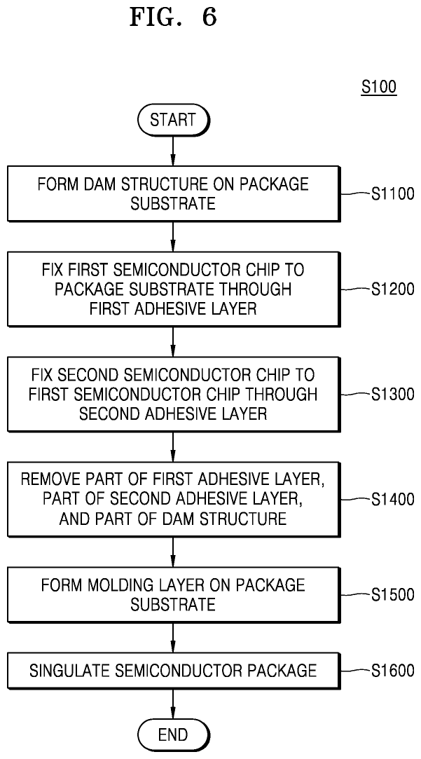

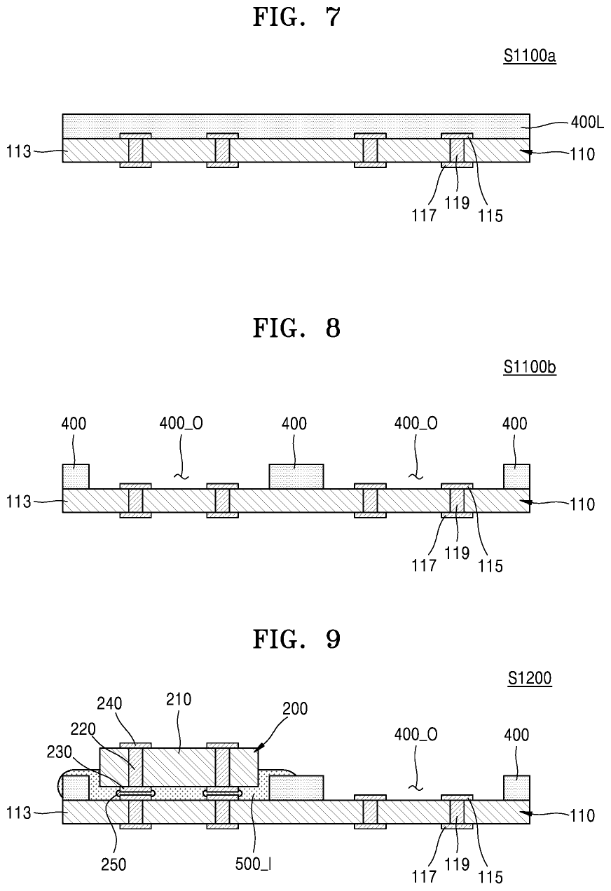

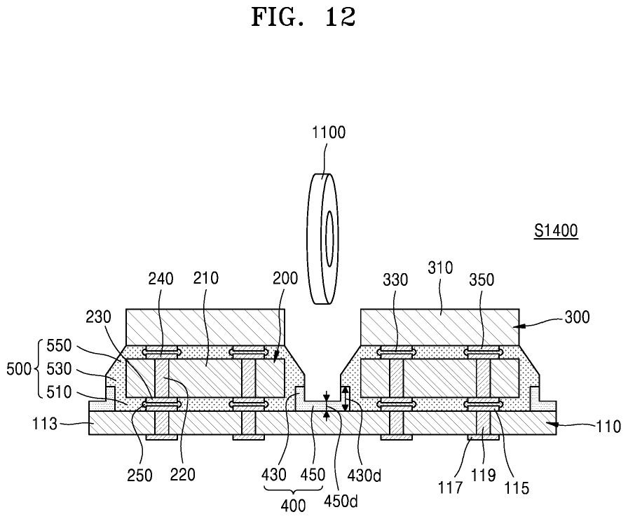

FIG. 6 is a flowchart of a method S100 of manufacturing a semiconductor package, according to an example embodiment of the inventive concept. FIGS. 7 to 14 are views showing operations of the method S100 of manufacturing a semiconductor package, according to an example embodiment of the inventive concept. The method S100 of manufacturing a semiconductor package, according to an example embodiment of the inventive concept, may be a method of manufacturing the semiconductor package 10 described with reference to FIGS. 1 to 3.

Referring to FIG. 6, the method S100 of manufacturing a semiconductor package, according to an example embodiment of the inventive concept, may include operation S1100 of forming the dam structure 400 on the package substrate 110, operation S1200 of fixing the first semiconductor chip 200 to the package substrate 110 through a first adhesive layer 500_I, operation S1300 of fixing the second semiconductor chip 300 to the first semiconductor chip 200 through a second adhesive layer 500_II, operation S1400 of removing a part of the first adhesive layer 500_I, a part of the second adhesive layer 500_II, and a part of the dam structure 400, operation S1500 of forming the molding layer 600 on the package substrate 110, and operation S1600 of singulating the semiconductor package.

Referring to FIGS. 6, 7, and 8 together, the method S100 of manufacturing a semiconductor package, according to an example embodiment of the inventive concept, may include operation S1100 of forming the dam structure 400 on the package substrate 110.

Operation S1100 may include operation S1100a of forming a dam layer 400L on the package substrate 110 and operation S1100b of forming the dam structure 400 by patterning the dam layer 400L.

Before operation S1100 is performed, a carrier substrate (not shown) may be attached under the package substrate 110. In an example embodiment, the carrier substrate may include a material having stability with respect to various manufacturing processes for the semiconductor package.

To separate and remove the carrier substrate later through laser ablation, the carrier substrate may be a transparent substrate. Selectively, to separate and remove the carrier substrate later through heating, the carrier substrate may be a heat-resistant substrate.

In an example embodiment, the carrier substrate may be a glass substrate. Alternatively, in another example embodiment, the carrier substrate may include, but is not limited to, a heat-resistant organic high-polymer material such as polyimide (PI), polyether ether ketone (PEEK), polyethersulfone (PES), polyphenylene sulfide (PPS), etc.

In an example embodiment, the package substrate 110 may be provided in a wafer level or a panel level. Therefore, operations S1100 to S1600 may be performed in the wafer level or the panel level.

In operation S1100a, the dam layer 400L may be coated onto the top surface of the package substrate 110. For example, the dam layer 400L may be provided on the top surface of the package substrate 110 through spin coating such that the dam layer 400L has a uniform thickness.

In an example embodiment, the dam layer 400L may be coated on the package substrate 110 such that the dam layer 400L has a thickness of about 8 micrometers or greater on the package substrate 110. For example, the dam layer 400L may have a thickness of about 8 micrometers to about 100 micrometers on the package substrate 110.

In an example embodiment, the material of the dam layer 400L may include at least any one of a PID material and PSPI, which are capable of being subject to the photolithography process.

The dam layer 400L may include a material capable of being subject to the photolithography process, and the dam layer 400L may be patterned by a general photolithography process in operation S1100b.

Thus, in operation S1100b, the dam structure 400 described with reference to FIGS. 1 to 3 may be formed. By performing operation S1100b, the dam structure 400 may include a dam opening 400_0 that exposes the upper substrate pad 115 of the package substrate 110 and provides a space having the first semiconductor chip 200 mounted thereon.

However, without being limited thereto, operation S1100 of forming the dam structure 400 on the package substrate 110 may include an operation of forming a photoresist material layer (not shown) on the top surface of the package substrate 110, an operation of forming an opening in which the dam structure 400 is to be arranged, by patterning the photoresist material layer, an operation of forming the dam structure 400 by filling the opening with a dam layer, and an operation of removing the photoresist material layer.

When the dam structure 400 is formed through the foregoing process, the material of the dam structure 400 may include at least any one of Sift and an EMC.

Referring to FIGS. 6 and 9, the method S100 of manufacturing the semiconductor package 10, according to an example embodiment of the inventive concept, may include operation S1200 of fixing the first semiconductor chip 200 to the package substrate 110 through the first adhesive layer 500_I.

In an example embodiment, in operation S1200, the first semiconductor chip 200 may be mounted on the package substrate 110 such that the first chip connection terminal 250 of the first semiconductor chip 200 contacts the upper substrate pad 115 of the package substrate 110.

In an example embodiment, before operation S1200 is performed, the first adhesive layer 500_I may be attached or applied to the bottom surface of the first semiconductor chip 200. The first adhesive layer 500_I may not be attached or applied to the bottom surface of the first chip connection terminal 250.

In an example embodiment, in operation S1200, the first chip connection terminal 250 of the first semiconductor chip 200 may be integrated with the upper substrate pad 115 through a thermal compression process. As the thermal compression process is performed, the first adhesive layer 500_I may increase in fluidity as a result of the heat generated during the thermal compression process, for example. Therefore, as the fluidity of the first adhesive layer 500_I is increased, when a part of the first adhesive layer 500_I is pressed by the bottom surface of the first semiconductor chip 200, at least a part of the first adhesive layer 500_I may overflow so as to be seated on the top surface of the dam structure 400.

In an example embodiment, by performing operation S1200, a part of the first adhesive layer 500_I may be disposed between the first semiconductor chip 200 and the package substrate 110 to surround the first chip connection terminal 250, and another part of the first adhesive layer 500_I may be disposed on a side portion of the first semiconductor chip 200 and on the top surface of the dam structure 400.

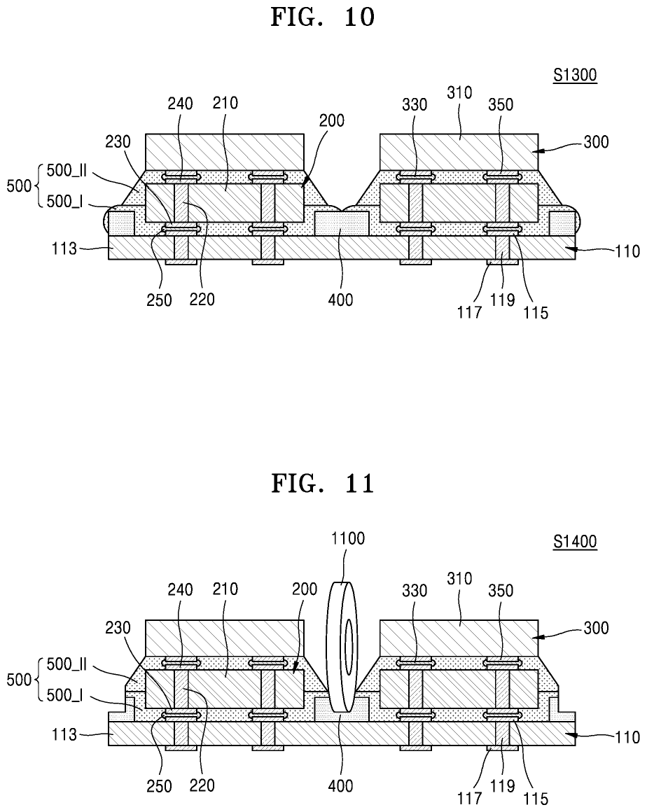

Referring to FIGS. 6 and 10 together, the method S100 of manufacturing the semiconductor package 10, according to an example embodiment of the inventive concept, may include operation S1300 of fixing the second semiconductor chip 300 to the first semiconductor chip 200 through the second adhesive layer 500_II.

In an example embodiment, in operation S1300, the second semiconductor chip 300 may be mounted on the first semiconductor chip 200 such that the second chip connection terminal 350 of the second semiconductor chip 300 contacts the first upper chip pad 240 of the first semiconductor chip 200.

In an example embodiment, before operation S1300 is performed, the second adhesive layer 500_II may be attached to the bottom surface of the second semiconductor chip 300. The second adhesive layer 500_II may not be attached or applied to the bottom surface of the second chip connection terminal 350.

In an example embodiment, in operation S1300, the second chip connection terminal 350 of the second semiconductor chip 300 may be integrated with the first upper chip pad 240 of the first semiconductor chip 200 through the thermal compression process. As the thermal compression process is performed, the second adhesive layer 500_II may increase in fluidity as a result of the heat generated during the thermal compression process, for example. Therefore, as the fluidity of the second adhesive layer 500_II is increased, when a part of the second adhesive layer 500_II is pressed by the bottom surface of the second semiconductor chip 300, at least a part of the second adhesive layer 500_II may overflow so as to be seated on the first adhesive layer 500_I to surround at least a part of the first semiconductor chip 200.

In an example embodiment, by performing operation S1300, a part of the second adhesive layer 500_II may be disposed between the first semiconductor chip 200 and the second semiconductor chip 300 to surround the second chip connection terminal 350, and another part of the second adhesive layer 500_II may be disposed on a side portion of the first semiconductor chip 200 to surround at least a part of the side surface of the first semiconductor chip 200.

The first adhesive layer 500_I and the second adhesive layer 500_II may include substantially the same material, and thus may be integrated.

Referring to FIGS. 6, 11, and 12 together, the method S100 of manufacturing the semiconductor package 10, according to an example embodiment of the inventive concept, may include operation S1400 of removing a part of the first adhesive layer 500_I, a part of the second adhesive layer 500_II, and a part of the dam structure 400.

In an example embodiment, operation S1400 may include an operation of physically etching the part of the first adhesive layer 500_I, the part of the second adhesive layer 500_II, and the part of the dam structure 400 through rotation of the dicing blade 1100.

In an example embodiment, by performing operation S1400, the cross-section of the dam structure 400 may have a shape of the alphabetical letter L or a left and right reversed shape of the alphabetical letter L.

More specifically, the dam structure 400 may include the first dam portion 430 that has the first length 430_d in the vertical direction and overlaps a part of the adhesive layer 500 in the vertical direction and the second dam portion 450 that is connected to the first dam portion 430 and extends from the outer side of the first dam portion 430. The second dam portion 450 has the second length 450_d that is less than the first length 430_d in the vertical direction.

In operation S1400, at least a part of the dam structure 400 and at least a part of the adhesive layer 500 may be removed by the dicing blade 1100, such that an outer surface of the first dam portion 430 and a side surface of the adhesive layer 500 may be arranged on the same plane.

In addition, by performing operation S1400, the first dam portion 430 of the dam structure 400 may overlap a part of the adhesive layer 500 in the vertical direction. That is, the top surface of the first dam portion 430 of the dam structure 400 may contact the adhesive layer 500, and the top surface of the second dam portion 450 of the dam structure 400 may be exposed (i.e., not covered or overlapped by the adhesive layer 500 in the vertical direction).

By performing operation S1400, the adhesive layer 500 may include the first adhesive portion 510 disposed between the first semiconductor chip 200 and the package substrate 110 and overlapping the first semiconductor chip 200 in the vertical direction, the second adhesive portion 530 disposed on an outer side of the first semiconductor chip 200 and has at least a part contacting the top surface of the first dam portion 430, and the third adhesive portion 550 disposed between the first semiconductor chip 200 and the second semiconductor chip 300 and overlapping the second semiconductor chip 300 in the vertical direction.

In an example embodiment, in operation S1400, the dicing blade 1100 may remove the adhesive layer 500 supported by the dam structure 400, and thus may not remove the package substrate 110 arranged under the dam structure 400. Hence, in operation S1400, physical damage to the package substrate 110 may be prevented from occurring due to the dicing blade 1100.

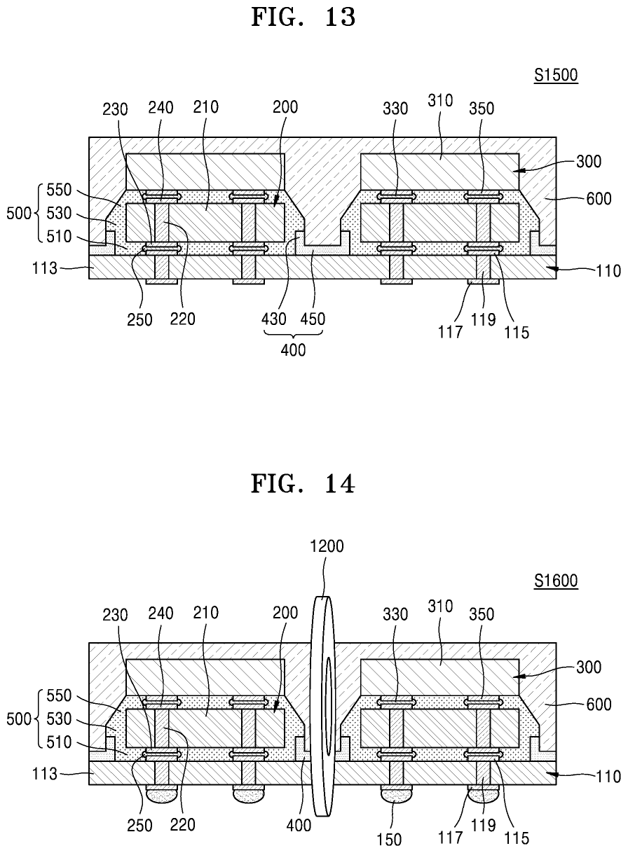

Referring to FIGS. 6 and 13 together, the method S100 of manufacturing a semiconductor package, according to an example embodiment of the inventive concept, may include operation S1500 of forming the molding layer 600 on the package substrate 110.

In an example embodiment, in operation S1500, the molding layer 600 may be formed on the package substrate 110 to surround the dam structure 400, the adhesive layer 500, and the second semiconductor chip 300.

In an example embodiment, the molding layer 600 may cover the top surface of the second semiconductor chip 300. However, without being limited thereto, the molding layer 600 may expose (i.e., not cover) the top surface of the second semiconductor chip 300.

For example, operation S1500 may include an operation of forming the molding layer 600 on the package substrate 110 and an operation of grinding a part of the molding layer 600 such that a surface of the molding layer 600 and the top surface of the second semiconductor chip 300 are on the same plane.

Referring to FIGS. 6 and 14 together, the method S100 of manufacturing a semiconductor package, according to an example embodiment of the inventive concept, may include operation S1600 of singulating the semiconductor package.

In an example embodiment, before operation S1600 is performed, the package connection terminal 150 may be attached to the lower substrate pad 117 of the package substrate 110. However, without being limited thereto, the operation of attaching the package connection terminal 150 to the lower substrate pad 117 may be performed after operation S1600.

In an example embodiment, in operation S1600, a dicing blade 1200 may singulate a structure of operation S1500. For example, in operation S1600, the dicing blade 1200 may cut a scribe lane of the package substrate 110. Therefore, the structure of operation S1500 may be singulated.

In an example embodiment, in operation S1600, the dicing blade 1200 may cut the molding layer 600, the second dam portion 450 of the dam structure 400, and the package substrate 110. That is, the dicing blade 1200 may not cut the adhesive layer 500.

The method S100 of manufacturing a semiconductor package, according to an example embodiment of the inventive concept, may include an operation of removing a part of the adhesive layer 500 supported by the dam structure 400 through the dicing blade 1100, thereby preventing physical damage to the package substrate 110 from occurring due to the dicing blade 1100.

Moreover, the adhesive layer 500 of the semiconductor package 10 manufactured using the method S100 of manufacturing a semiconductor package, according to an example embodiment of the inventive concept, may not be exposed to the side surface of the semiconductor package 10, thereby reducing delamination between the adhesive layer 500 and the molding layer 600 and improving the structural reliability of the semiconductor package 10.

While the inventive concept has been particularly shown and described with reference to embodiments thereof, it will be understood that various changes in form and details may be made therein without departing from the spirit and scope of the following claims.

What is claimed is:

1. A semiconductor package comprising:
a package substrate;
a first semiconductor chip disposed on the package substrate;
a second semiconductor chip stacked on the first semiconductor chip;
a dam structure disposed on the package substrate and surrounding the first semiconductor chip and the second semiconductor chip, the dam structure including a first dam portion comprising an inner surface having a first length in a vertical direction and facing a side surface of the first semiconductor chip, and an outer surface opposing the inner surface, and
a second dam portion connected to the first dam portion and extending from the outer surface of the first dam portion, and having a second length less than the first length in the vertical direction;
an adhesive layer disposed on the package substrate, the adhesive layer including
a first adhesive portion disposed between the first semiconductor chip and the package substrate and overlapping the first semiconductor chip in the vertical direction,
a second adhesive portion disposed on an outer side of the first semiconductor chip and comprising at least a part contacting a top surface of the first dam portion, and
a third adhesive portion disposed between the first semiconductor chip and the second semiconductor chip and overlapping the second semiconductor chip in the vertical direction; and
a molding layer disposed on the package substrate and contacting a top surface of the second dam portion.

2. The semiconductor package of claim 1, wherein a material of the dam structure comprises at least any one of a photo imageable dielectric (PID) material and a photosensitive polyimide (PSPI), which are capable of being subject to a photolithography process.

3. The semiconductor package of claim 1, wherein a material of the dam structure comprises at least any one of silicon oxide (Sift) and an epoxy molding compound (EMC).

4. The semiconductor package of claim 1, wherein a material of the dam structure and a material of the molding layer are the same as each other.

5. The semiconductor package of claim 1, wherein the molding layer contacts the outer surface of the first dam portion and the top surface of the second dam portion, and
the adhesive layer contacts the top surface of the first dam portion and the inner surface of the first dam portion.

6. The semiconductor package of claim 1, wherein a side surface of the molding layer and an outer surface of the second dam portion are disposed on the same plane, and
the adhesive layer does not overlap the second dam portion in the vertical direction.

7. The semiconductor package of claim 1, wherein the first length of the first dam portion is about 8 micrometers to about 100 micrometers.

8. The semiconductor package of claim 1, wherein the top surface of the first dam portion is disposed at a level lower than a top surface of the first semiconductor chip in the vertical direction.

9. The semiconductor package of claim 1, wherein the top surface of the second dam portion has a planar shape extending in a horizontal direction perpendicular to the vertical direction.

10. The semiconductor package of claim 1, wherein the top surface of the second dam portion has a curved surface shape, and
the second length of the second dam portion gradually decreases in a direction away from the side surface of the first semiconductor chip.

11. The semiconductor package of claim 1,
wherein the first semiconductor chip includes
a first semiconductor substrate comprising a first active layer,
a first lower chip pad disposed on a bottom surface of the first semiconductor substrate,
a chip through electrode passing through at least a part of the first semiconductor substrate in the vertical direction and connected to the first active layer,
a first upper chip pad disposed on a top surface of the first semiconductor substrate and connected to the chip through electrode, and
a first chip connection terminal disposed between the first lower chip pad and the package substrate, and
wherein the second semiconductor chip includes
a second semiconductor substrate comprising a second active layer,
a second lower chip pad disposed on a bottom surface of the second semiconductor substrate, and
a second chip connection terminal disposed between the second lower chip pad and the first upper chip pad.

12. The semiconductor package of claim 11, wherein the first adhesive portion surrounds the first chip connection terminal, and
the third adhesive portion surrounds the second chip connection terminal.

13. A semiconductor package comprising:
a package substrate;
a semiconductor chip disposed on the package substrate;
a dam structure disposed on the package substrate and surrounding the semiconductor chip, the dam structure including
a first dam portion having a first length in a vertical direction, and
a second dam portion connected to the first dam portion and extending from an outer side of the first dam portion, and having a second length less than the first length in the vertical direction;
an adhesive layer disposed on the package substrate, the adhesive layer including
a first adhesive portion disposed between the semiconductor chip and the package substrate and overlapping the semiconductor chip in the vertical direction, and
a second adhesive portion disposed on an outer side of the semiconductor chip and comprising at least a part contacting a top surface of the first dam portion; and
a molding layer disposed on the package substrate.

14. The semiconductor package of claim 13, wherein the outer side of the first dam portion and an outer surface of the second adhesive portion are disposed on the same plane.

15. The semiconductor package of claim 13, wherein the molding layer contacts an outer surface of the first dam portion and the top surface of the second dam portion, and
the adhesive layer contacts the top surface of the first dam portion and an inner surface of the first dam portion.

16. The semiconductor package of claim 13, wherein a side surface of the molding layer and an outer surface of the second dam portion are disposed on the same plane, and
the adhesive layer is does not overlap the second dam portion in the vertical direction.

17. The semiconductor package of claim 13, wherein the top surface of the second dam portion has a curved surface shape, and
the second length of the second dam portion gradually decreases in a direction away from a side surface of the semiconductor chip.

18. A semiconductor package comprising:
a package substrate;
a first semiconductor chip disposed on the package substrate, the first semiconductor chip including
a first semiconductor substrate comprising a first active layer,
a first lower chip pad disposed on a bottom surface of the first semiconductor substrate,
a chip through electrode passing through at least a part of the first semiconductor substrate in a vertical direction and connected to the first active layer,
a first upper chip pad disposed on a top surface of the first semiconductor substrate and connected to the chip through electrode, and
a first chip connection terminal disposed between the first lower chip pad and the package substrate;
a second semiconductor chip disposed on the first semiconductor chip, the second semiconductor chip including
a second semiconductor substrate comprising a second active layer,
a second lower chip pad disposed on a bottom surface of the second semiconductor substrate, and
a second chip connection terminal being disposed between the second lower chip pad and the first upper chip pad;
a dam structure disposed on the package substrate and surrounding the first semiconductor chip and the second semiconductor chip, the dam structure including
a first dam portion comprising an inner surface having a first length in a vertical direction and facing a side surface of the first semiconductor chip, and an outer surface opposing the inner surface, and
a second dam portion connected to the first dam portion and extending from the outer surface of the first dam portion, and having a second length less than the first length in the vertical direction;
an adhesive layer disposed on the package substrate, the adhesive layer including
a first adhesive portion overlapping the first semiconductor chip in the vertical direction and disposed between the first semiconductor chip and the package substrate to surround the first chip connection terminal,
a second adhesive portion disposed on an outer side of the first semiconductor chip and comprising at least a part contacting a top surface of the first dam portion, and
a third adhesive portion overlapping the second semiconductor chip in the vertical direction and disposed between the first semiconductor chip and the second semiconductor chip to surround the second chip connection terminal; and
a molding layer disposed on the package substrate and contacting a top surface of the second dam portion.

19. The semiconductor package of claim 18, wherein the first length of the first dam portion is about 8 micrometers to about 100 micrometers, and
the top surface of the first dam portion is disposed at a level lower than a top surface of the first semiconductor chip in the vertical direction.

20. The semiconductor package of claim 18, wherein a material of the dam structure and a material of the molding layer are the same as each other.
